(19) United States
(12) Patent Application Publication
(10) Pub. No.: US 2026/0080967 A1
(43) Pub. Date: Mar. 19, 2026

(54) MEMORY SYSTEM AND WRITING METHOD FOR SEMICONDUCTOR MEMORY

(71) Applicant: Kioxia Corporation, Tokyo (JP)

(72) Inventors: Itaru HIDA, Yokohama (JP); Toshiyuki YAMAGISHI, Tokyo (JP)

(73) Assignee: Kioxia Corporation, Tokyo (JP)

(21) Appl. No.: 19/074,600

(22) Filed: Mar. 10, 2025

(30) Foreign Application Priority Data
Sep. 17, 2024 (JP) 2024-160041

(51) Int. Cl. G11C 29/52

(52) U.S. Cl. CPC G11C 29/52

(57) ABSTRACT

According to one embodiment, a memory controller generates first write data by executing an error suppression coding in regard to data, based on a first coding parameter; calculates an error rate for each of word lines from the first read data corresponding to the first write data, and selects a first word line from the word lines, based on the error rate. The memory controller generates second write data by executing the error suppression coding while varying the first coding parameter, in regard to data that is to be written in a first memory cell coupled to the first word line; sets a second coding parameter, based on an error rate of second read data corresponding to the second write data; and executes the error suppression coding, based on the second coding parameter, in regard to data that is to be written in the first memory cell.

### CROSS-REFERENCE TO RELATED APPLICATIONS

This application is based upon and claims the benefit of priority from prior Japanese Patent Application No. 2024-160041, filed Sep. 17, 2024, the entire contents of which are incorporated herein by reference.

### FIELD

Embodiments described herein relate generally to a memory system and a writing method for a semiconductor memory.

### BACKGROUND

A memory system is composed of, for example, a semiconductor memory including a NAND flash memory, and a memory controller that controls the semiconductor memory.

### BRIEF DESCRIPTION OF THE DRAWINGS

FIG. 1 is a block diagram illustrating a configuration of a memory system according to a first embodiment.

FIG. 2 is a block diagram illustrating a circuit configuration of a semiconductor memory according to the first embodiment.

FIG. 3 is a circuit diagram of a block in a memory cell array according to the first embodiment.

FIG. 4 is a diagram illustrating a relationship between possible threshold voltage distributions of memory cell transistors and data according to the first embodiment.

FIG. 5 is a diagram illustrating a flow of data of a write operation and a read operation in the memory system according to the first embodiment.

FIG. 6 is a flowchart illustrating a write operation in the memory system according to the first embodiment.

FIG. 7 is a diagram illustrating data formats to which various coding rates are applied according to the first embodiment.

FIG. 8 is a diagram illustrating an example of a case where coding rates are set for a plurality of pages according to the first embodiment.

FIG. 9 is a flowchart illustrating a process of optimization of coding parameters in error suppression coding of the memory system according to the first embodiment.

FIG. 10 is a diagram illustrating information stored in a RAM of the memory controller according to the first embodiment.

FIG. 11 is a flowchart illustrating an optimizing process of a state control variable according to the first embodiment.

FIG. 12 is a graph illustrating variations of error rates by an optimizing process in error suppression coding of the memory system according to the first embodiment.

FIG. 13 is a diagram illustrating error rates in regard to word lines in a case where error suppression coding is performed for data that is written in memory cells of a word line in a target block according to the first embodiment.

FIG. 14 is a flowchart illustrating an optimizing process of coding parameters in error suppression coding of a memory system according to a second embodiment.

FIG. 15 is a flowchart illustrating an optimizing process of a state control variable according to the second embodiment.

FIG. 16 is a graph illustrating variations of error rates by an optimizing process in error suppression coding of the memory system according to the second embodiment.

### DETAILED DESCRIPTION

In general, according to one embodiment, a memory system includes a semiconductor memory and a memory controller. The semiconductor memory includes a plurality of word lines to which a plurality of memory cells are coupled. The memory controller is configured to execute error suppression coding for data that is to be written in the semiconductor memory. The memory controller is configured to generate first write data by executing the error suppression coding, based on a first coding parameter, in regard to data that is to be written in the memory cells coupled to the word lines. The memory controller is configured to read out the first write data that is written in the memory cells, as first read data. The memory controller is configured to calculate an error rate for each of the word lines from the first read data, and select a first word line from the word lines, based on the error rate for each of the word lines. The memory controller is configured to generate second write data by executing the error suppression coding while varying the first coding parameter, in regard to data that is to be written in a first memory cell coupled to the first word line. The memory controller is configured to set a second coding parameter, based on an error rate of second read data corresponding to the second write data. The memory controller is configured to execute error suppression coding, based on the second coding parameter, in regard to data that is to be written in the first memory cell coupled to the first word line.

Hereinafter, embodiments are described with reference to the accompanying drawings. In the description below, structural elements with identical functions and structures are denoted by like reference signs. In addition, the embodiments to be described below exemplarily illustrate devices and methods for embodying technical concepts of the embodiments, and do not specifically restrict the materials, shapes, structures, arrangements and the like of the structural components to those described below.

Functional blocks can be implemented by hardware, computer software, or a combination of hardware and computer software. It is not necessary that the functional blocks are distinguished as in examples described below. For example, some functions may be executed by functional blocks different from the functional blocks illustrated.

In addition, a functional block illustrated may be divided into more specific functional sub-blocks.

### 1. First Embodiment

For example, in a case of executing write and read of data in a memory system, error suppression coding and decoding is known as one technology for improving the reliability of data in the write and read. In the error suppression coding and decoding, coding (for example, data conversion) is performed for data that is to be written in a memory device, and decoding is performed for data that is read from the memory device, thereby reducing an error rate of data and suppressing exhaustion of memory cells. In the error suppression coding and decoding, for example, asymmetric coding (AC) is used, or page symmetric coding (PSC) is used.

Hereinafter, a configuration of the memory system is first described, and then error suppression coding and decoding in the operation of the memory system is described.

### 1.1. Configuration of Memory System

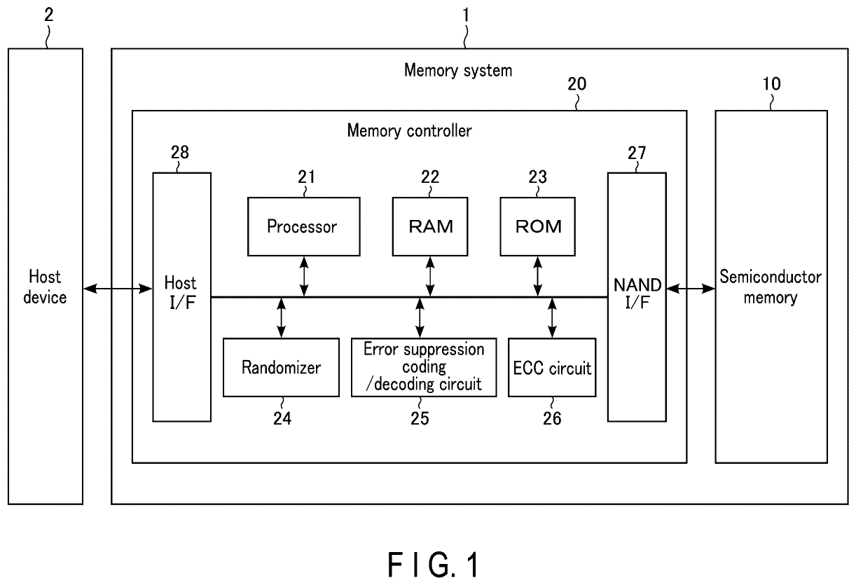

To begin with, a configuration of a memory system 1 of a first embodiment is described. FIG. 1 is a block diagram illustrating a configuration of the memory system according of the first embodiment. The memory system 1 is coupled to an external host device 2, and can execute various operations in accordance with instructions from the host device 2. The memory system 1 includes a semiconductor memory 10 and a memory controller 20.

The semiconductor memory 10 includes, for example, a NAND flash memory in which memory cells (also referred to as memory cell transistors) are two-dimensionally or three-dimensionally arranged, and stores data in a nonvolatile manner. The details of the semiconductor memory 10 will be described later.

The memory controller 20 is coupled to the semiconductor memory 10 via a NAND bus. The memory controller 20 controls the semiconductor memory 10. The NAND bus transmits and receives signals according to a NAND interface. The memory controller 20 is also coupled to the host device 2 via a host bus. Responding to an instruction received from the host device 2, the memory controller 20 accesses the semiconductor memory 10.

The above-described semiconductor memory 10 and memory controller 20 may include, for example, a single semiconductor device by a combination thereof. Examples of such a semiconductor device include memory cards including an SD™ card, and an SSD (solid state drive). In addition, the memory controller 20 may be, for example, an SoC (system-on-chip), or the like.

The host device 2 is, for example, a personal computer, a mobile terminal such as a smartphone, or a digital camera. The host bus is, for example, a bus according to an SD™ interface.

### 1.1.1. Memory Controller

Referring to FIG. 1, a configuration of the memory controller 20 is described. The memory controller 20 includes a processor 21, a RAM (random access memory) 22, a ROM (read-only memory) 23, a randomizer 24, an error suppression coding/decoding circuit 25, an ECC (error checking and correction) circuit 26, a NAND interface circuit (NAND I/F) 27, and a host interface circuit (host I/F) 28.

The processor 21 controls an overall operation of the memory controller 20. For example, in a case where the processor 21 receives a write instruction from the host device 2, the processor 21 responds to the write instruction and issues a write instruction to the NAND interface circuit 27. in a case where the processor 21 receives a read instruction and an erase instruction, the processor 21 similarly responds to these instructions and issues a read instruction and an erase instruction to the NAND interface circuit 27.

The processor 21 executes various processes for managing the semiconductor memory 10, such as wear leveling. Note that the operation of the memory controller 20 to be described below may be implemented by the processor 21 executing software or firmware, or may be implemented by hardware. The processor 21 includes, for example, a CPU (central processing unit).

The RAM 22 is used as a working area of the processor 21. The RAM 22 temporarily stores firmware for managing the semiconductor memory 10, various management tables such as a logical/physical address conversion table, and data.

The RAM 22 stores, for example, user data received from the host device 2, data processed by the randomizer 24, error suppression coding/decoding circuit 25 and ECC circuit 26, and write data that is to be written in the semiconductor memory 10. In addition, the RAM 22 stores read data received from the semiconductor memory 10, and data that is to be sent to the host device 2. The RAM 22 stores, for example, coding parameters used in the error suppression coding and decoding by the error suppression coding/decoding circuit 25. The coding parameters will be described later.

The RAM 22 is a volatile memory. The RAM 22 is, for example, a semiconductor memory such as a dynamic random access memory (DRAM) or a static random access memory (SRAM).

The ROM 23 stores, for example, software or firmware executed by the processor 21, and various parameters necessary for the execution of the processor 21. The ROM 23 is a nonvolatile memory. The ROM 23 is, for example, an EEPROM™ (electrically erasable programmable read-only memory).

The randomizer 24 randomizes user data in order to equally distribute memory cells in states that the memory cells in the semiconductor memory 10 can take. The randomizer 24 includes, for example, a linear feedback shift register. The linear feedback shift register generates a pseudo-random number that is uniquely found for an input value. The processor 21 calculates an exclusive OR between the pseudo-random number and the user data, and generates randomized data (hereinafter referred to as “randomize data”). In addition, the randomizer 24 de-randomizes the randomize data that is read from the semiconductor memory 10, and restores the randomize data to the user data before randomized. The states that the memory cells can take will be described later.

The error suppression coding/decoding circuit 25 performs error suppression coding for reducing an error rate with respect to the data that is to be written in the semiconductor memory 10. In addition, the error suppression coding/decoding circuit 25 performs error suppression decoding with respect to the data that is read from the semiconductor memory 10. For example, in a write operation, the error suppression coding/decoding circuit 25 performs error suppression coding by using coding parameters, with respect to the user data received from the host device 2 or the randomize data. In a read operation, the error suppression coding/decoding circuit 25 performs error suppression decoding by using coding parameters, with respect to the read data received from the semiconductor memory 10 or the data that was subjected to error correction decoding. The details of the error suppression coding/decoding circuit 25 will be described later.

The ECC circuit 26 executes a process relating to error correction of data. The ECC circuit 26 executes a process relating to detection and correction of an error with respect to the data that is to be written in the semiconductor memory 10 and the data that was read out of the semiconductor memory 10. Specifically, at a time of a write operation, the ECC circuit 26 generates a parity, based on write data to be written in the semiconductor memory 10, and imparts the generated parity to the write data. At a time of a read operation, the ECC circuit 26 generates a syndrome, based on the read data received from the semiconductor memory 10, and detects and corrects an error of the read data, based on the generated syndrome.

The NAND interface circuit 27 is coupled to the semiconductor memory 10 via the NAND bus, and controls the communication with the semiconductor memory 10. Based on an instruction received from the processor 21, the NAND interface circuit 27 sends various signals, commands and data to the semiconductor memory 10. In addition, the NAND interface circuit 27 receives various signals and data from the semiconductor memory 10.

The host interface circuit 28 is coupled to the host device 2 via the host bus, and controls the communication with the host device 2. The host interface circuit 28 transfers instructions and data, which are received from the host device 2, to the processor 21 and the RAM 22. In addition, responding to an instruction from the processor 21, the host interface circuit 28 sends the data in the RAM 22 to the host device 2.

### 1.1.2. Semiconductor Memory

The semiconductor memory 10 of the first embodiment is described.

### 1.1.2.1. Circuit Configuration of Semiconductor Memory

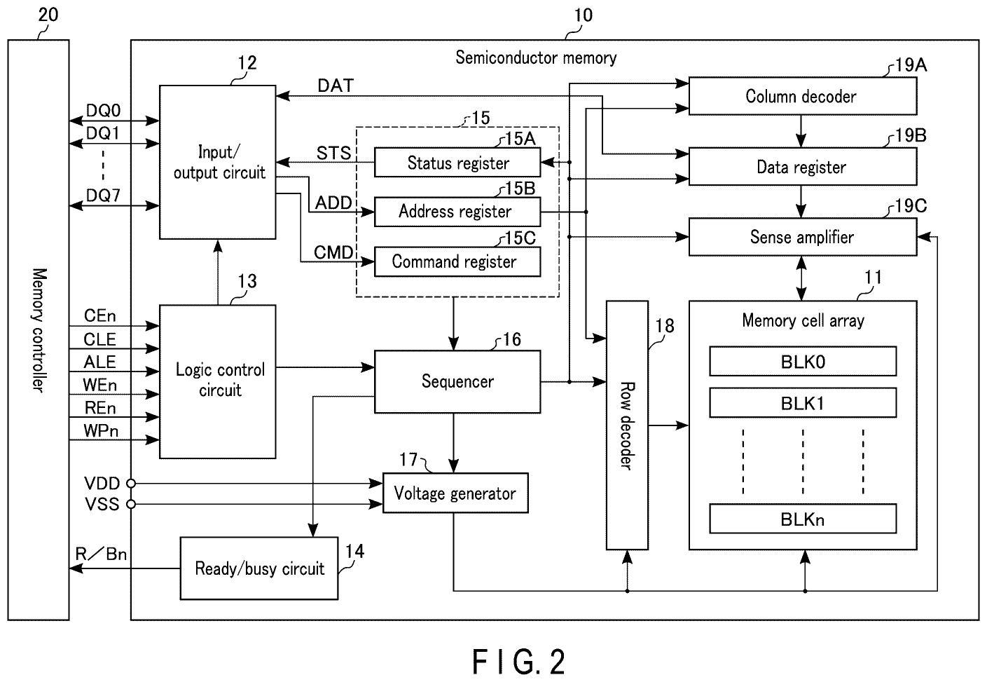

To begin with, a circuit configuration of the semiconductor memory 10 of the first embodiment is described. FIG. 2 is a block diagram illustrating the circuit configuration of the semiconductor memory of the first embodiment.

The semiconductor memory 10 includes a memory cell array 11, an input/output circuit 12, a logic control circuit 13, a ready/busy circuit 14, a register group 15, a sequencer (or control circuit) 16, a voltage generator 17, a row decoder 18, a column decoder 19A, a data register 19B, and a sense amplifier 19C. The register group 15 includes a status register 15A, an address register 15B, and a command register 15C.

The memory cell array 11 includes one or more blocks BLK0, BLK1, BLK2, . . . BLKn (n is an integer of 0 or more). Each of the blocks BLK0 to BLKn includes a plurality of memory cell transistors (hereinafter, also referred to as “memory cells”) associated with rows and columns. The memory cell transistor is an electrically erasable and programmable nonvolatile memory cell. The memory cell array 11 includes a plurality of word lines, a plurality of bit lines, and a source line for applying voltages to the memory cell transistors. A specific configuration of the block BLKn is described later.

The input/output circuit 12 and logic control circuit 13 are coupled to the memory controller 20 via input/output terminals (or NAND bus). The input/output circuit 12 transmits and receives I/O signals DQ (for example, DQ0, DQ1, DQ2, . . . DQ7) via the input/output terminals to and from the memory controller 20. The I/O signals DQ communicate commands, addresses, data, and the like.

The logic control circuit 13 receives external control signals via input/output terminals (or NAND bus) from the memory controller 20. The external control signals include, for example, a chip enable signal CEn, a command latch enable signal CLE, an address latch enable signal ALE, a write enable signal WEn, a read enable signal REn, and a write protect signal WPn. Character “n” added to the signal name indicates that the signal is “active low”.

In a case where a plurality of semiconductor memories 10 are mounted, the chip enable signal CEn enables selection of the semiconductor memory 10, and is asserted at a time of selecting this semiconductor memory 10. The command latch enable signal CLE enables a command, which is transmitted as a signal DQ, to be latched in the command register 15C. The address latch enable signal ALE enables an address, which is transmitted as a signal DQ, to be latched in the address register 15B. The write enable signal WEn enables data, which is transmitted as a signal DQ, to be stored in the input/output circuit 12. The read enable signal REn enables data, which is read from the memory cell array 11, to be output as a signal DQ. The write protect signal WPn is asserted at a time of prohibiting a write operation and an erase operation to the semiconductor memory 10.

The ready/busy circuit 14 generates a ready/busy signal R/Bn in accordance with the control from the sequencer 16. The ready/busy signal R/Bn indicates whether the semiconductor memory 10 is in a ready state or in a busy state. The ready state indicates a state in which the semiconductor memory 10 can accept an instruction from the memory controller 20. The busy state indicates a state in which the semiconductor memory 10 cannot accept an instruction from the memory controller 20. By receiving the ready/busy signal R/Bn from the semiconductor memory 10, the memory controller 20 can recognize whether the semiconductor memory 10 is in the ready state or in the busy state.

The status register 15A stores status information STS that is necessary for the operation of the semiconductor memory 10. In accordance with an instruction from the sequencer 16, the status register 15A transfers the status information STS to the input/output circuit 12.

The address register 15B stores an address ADD that is transferred from the input/output circuit 12. The address ADD includes a row address and a column address. The row address includes, for example, a block address that designates the block BLKn of an operation target, and a page address that designates a word line WL of an operation target in the designated block.

The command register 15C stores a command CMD that is transferred from the input/output circuit 12. The command CMD includes, for example, a write command that instructs the sequencer 16 to execute a write operation, a read command that instructs the sequencer 16 to execute a read operation, and an erase command that instructs the sequencer 16 to execute an erase operation.

An SRAM (static random access memory), for example, is used for each of the status register 15A, address register 15B and command register 15C.

The sequencer 16 receives a command from the command register 15C, and comprehensively controls the semiconductor memory 10 in accordance with a sequence based on the command.

The sequencer 16 controls the voltage generator 17, the row decoder 18, the column decoder 19A, the data register 19B, and the sense amplifier 19C, and executes a write operation, a read operation and an erase operation. Specifically, based on a write command received from the command register 15C, the sequencer 16 controls the voltage generator 17, the row decoder 18, the data register 19B and the sense amplifier 19C, and writes data in a plurality of memory cell transistors designated by the address ADD. In addition, based on a read command received from the command register 15C, the sequencer 16 controls the voltage generator 17, the row decoder 18, the column decoder 19A, the data register 19B and the sense amplifier 19C, and reads data from a plurality of memory cell transistors designated by the address ADD. Further, based on an erase command received from the command register 15C, the sequencer 16 controls the voltage generator 17, the row decoder 18, the column decoder 19A, the data register 19B and the sense amplifier 19C, and erases data stored in a block designated by the address ADD. Note that a circuit including the column decoder 19A and data register 19B is referred to as “column control circuit”.

The voltage generator 17 receives a power supply voltage VDD and a ground voltage VSS via power supply terminals from the outside of the semiconductor memory 10. The power supply voltage VDD is an external voltage that is supplied from the outside of the semiconductor memory 10. The ground voltage VSS is an external voltage that is supplied from the outside of the semiconductor memory 10, and is, for example, 0 V.

Using the power supply voltage VDD, the voltage generator 17 generates voltages necessary for the write operation, the read operation and the erase operation. The voltage generator 17 supplies the generated voltages to the memory cell array 11, the row decoder 18, and the sense amplifier 19C.

The row decoder 18 receives a row address from the address register 15B, and decodes the row address. Based on a decoded result of the row address, the row decoder 18 selects one of the blocks, and further selects a word line WL in the selected block BLKn. Moreover, the row decoder 18 transfers voltages, which are supplied from the voltage generator 17, to the selected block BLKn.

The column decoder 19A receives a column address from the address register 15B, and decodes the column address. Based on a decoded result of the column address, the column decoder 19A selects a latch circuit in the data register 19B.

The data register 19B includes a plurality of latch circuits. Each the latch circuit temporarily stores write data or read data.

At a time of a data read operation, the sense amplifier 19C senses and amplifies data that is read out from the memory cell transistor to the bit line. Further, the sense amplifier 19C temporarily stores read data DAT that is read from the memory cell transistor, and transfers the stored read data DAT to the data register 19B. In addition, at a time of a data write operation, the sense amplifier 19C temporarily stores write data DAT that is transferred from the input/output circuit 12 via the data register 19B. Further, the sense amplifier 19C transfers the write data DAT to the bit line.

Next, a circuit configuration of the memory cell array 11 in the semiconductor memory 10 of the first embodiment is described. The memory cell array 11 includes a plurality of blocks BLK0 to BLKn, as described above. Hereinafter, a circuit configuration of the block BLKn is described.

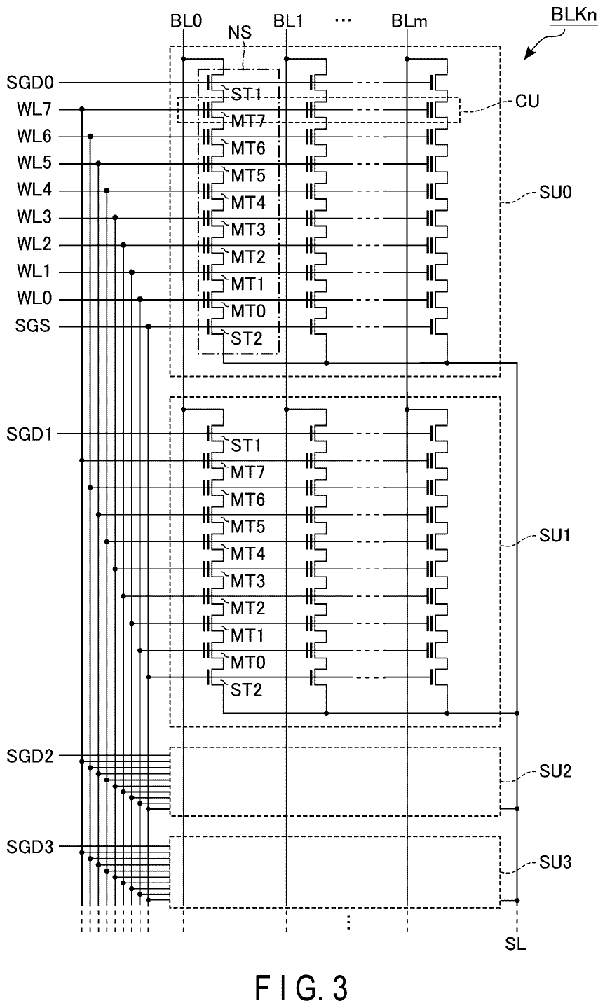

FIG. 3 is a circuit diagram of the block BLKn in the memory cell array 11. The block BLKn includes, for example, a plurality of string units SU0, SU1, SU2 and SU3. Hereinafter, it is assumed that the term “string unit SU” means each of the string units SU0 to SU3. The string unit SU includes a plurality of NAND strings (or memory strings) NS.

Here, for the purpose of simple description, an example is described in which the NAND string NS includes, for example, eight memory cell transistors MT0, MT1, MT2, . . . MT7, and two select transistors ST1 and ST2. Hereinafter, it is assumed that the term “memory cell transistor MT” means each of the memory cell transistors MT0 to MT7.

The memory cell transistor MT includes a control gate and a charge storage layer, and stores data in a nonvolatile manner. The memory cell transistors MT0 to MT7 are coupled in series between the source of the select transistor ST1 and the drain of the select transistor ST2. The memory cell transistor MT can store data of one bit, or data of two or more bits.

The gates of the select transistors ST1 included in the string unit SU0 are coupled to a select gate line SGD0. Similarly, the gates of the select transistors ST1 included in the string units SU1 to SU3 are coupled to select gate line SGD1 to SGD3. Each of the select gate line SGD0 to SGD3 is independently controlled by the row decoder 18.

The gates of the select transistors ST2 included in the string unit SU0 are coupled to a select gate line SGS. Similarly, the gates of the select transistors ST2 of the string units SU1 to SU3 are coupled to the select gate line SGS. Note that there is a case where individual select gate lines SGS are coupled to the gates of the select transistors ST2 of the string units SU0 to SU3, respectively. The select transistors ST1 and ST2 are used to select the string unit SU in various operations.

The control gates of the memory cell transistors MT0 to MT7 included in the block BLKn are coupled to word lines WL0 to WL7. Each of the word lines WL0 to WL7 is independently controlled by the row decoder 18.

Each of bit lines BL0, BL1, BL2, . . . BLm (m is an integer of 0 or more) is coupled to a plurality of blocks BLK0 to BLKn, and is coupled to one NAND string NS in the string unit SU included in the block BLKn. Specifically, each of the bit lines BL0 to BLm is coupled to the drains of the select transistors ST1 of the NAND strings NS in the same column among the NAND strings NS arranged in a matrix in the block BLKn. In addition, the source line SL is coupled to the blocks BLK0 to BLKn. Specifically, the source line SL is coupled to the sources of the select transistors ST2 included in the block BLKn.

In short, the string unit SU includes NAND strings NS coupled to different bit lines BL and coupled to an identical select gate line SGD. In addition, the block BLKn includes a plurality of string units SU having common word lines WL. Further, the memory cell array 11 includes a plurality of blocks BLK0 to BLKn having common bit lines BL.

The block BLKn is, for example, an erase unit of data. Specifically, the data stored in the memory cell transistors MT included in the block BLKn is erased batchwise. Note that the data may be erased in units of the string unit SU, or may be erased in units of a unit less than the string unit SU.

A plurality of memory cell transistors MT, which share a word line WL in one string unit SU, is referred to as “cell unit CU”. A set of 1-bit data, which the memory cell transistors MT included in the cell unit CU store, is referred to as “page”. The storage capacity of the cell unit CU varies in accordance with the number of bits of data that the memory cell transistor MT stores. For example, the cell unit CU stores 1-page data in a case where each memory cell transistor MT stores 1-bit data, the cell unit CU stores 2-page data in a case where each memory cell transistor MT stores 2-bit data, and the cell unit CU stores 3-page data in a case where each memory cell transistor MT stores 3-bit data.

A write operation and a read operation for the cell unit CU are executed in units of a page. In other words, the write operation and read operation are executed batchwise for the memory cell transistors MT coupled to one word line WL provided in one string unit SU.

Note that the number of string units included in the block BLKn is not limited to SU0 to SU3, and may be freely set. In addition, the number of NAND strings NS included in the string unit SU, and the number of memory cell transistors and the number of select transistors in the NAND string NS, can also be freely set. Moreover, the memory cell transistor MT may be a MONOS (metal-oxide-nitride-oxide-silicon) type using an insulating film as a charge storage layer, or may be an FG (floating gate) type using a conductive layer as a charge storage layer.

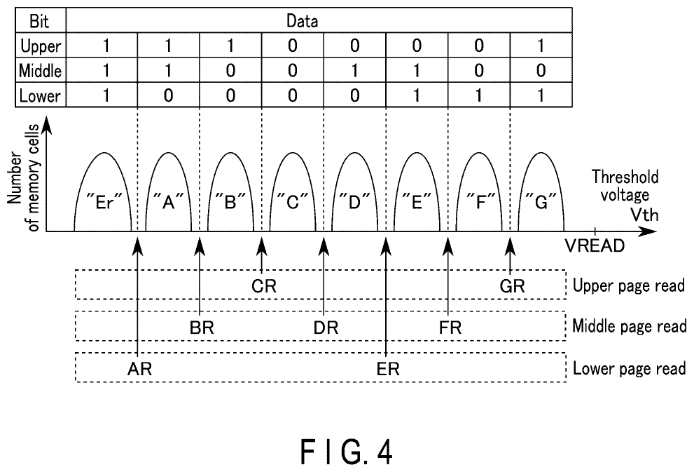

Next, a relationship between a threshold voltage distribution, which the memory cell transistors MT can have, and data, is described. FIG. 4 is a diagram illustrating a relationship between a threshold voltage distribution, which the memory cell transistors MT can have, and data.

Here, as a storage method of memory cell transistors MT, an example is described in which a TLC (Triple-Level Cell) method that is capable of storing 3-bit data in one memory cell transistor MT is applied. Note that the present embodiment is applicable to cases using other storage methods, such as an SLC (Single-Level Cell) method that is capable of storing 1-bit data in one memory cell transistor MT, an MLC (Multi-Level Cell) method that is capable of storing 2-bit data in one memory cell transistor MT, or a QLC (Quad-Level Cell) method that is capable of storing 4-bit data in one memory cell transistor MT.

The 3-bit data that the memory cell transistor MT can store is defined by a lower bit, a middle bit and an upper bit. In a case where the memory cell transistor MT stores three bits, the memory cell transistor MT can take any one of eight states corresponding to different threshold voltages. The eight states are referred to as states “Er”, “A”, “B”, “C”, “D”, “E”, “F”, and “G”, in the order from the lowest state. The memory cell transistors MT belonging to each of the states “Er”, “A”, “B”, “C”, “D”, “E”, “F”, and “G” form a distribution of threshold voltages as illustrated in FIG. 4.

For example, data “111”, “110”, “100”, “000”, “010”, “011”, “001” and “101” are allocated to the states “Er”, “A”, “B”, “C”, “D”, “E”, “F”, and “G”. The arrangement of bits is “ZYX”, if the lower bit is “X”, the middle bit is “Y” and the upper bit is “Z”. Note that the allocation between the threshold voltage distribution and the data can freely be set.

In order to read the data stored in the memory cell transistor MT of the read target, the state to which the threshold voltage of the memory cell transistor MT belongs is determined. In order to determine the state, read voltages AR, BR, CR, DR, ER, FR and GR are used.

A voltage VREAD is a voltage that is applied to the word line WL coupled to the memory cell transistors MT of the cell unit CU that is not the read target. The voltage VREAD is higher than the threshold voltages of the memory cell transistors MT in any one of the states. Thus, the memory cell transistors MT with the control gates, to which the voltage VREAD is applied, enter the ON state regardless of the data that the memory cell transistors MT store.

As described above, each memory cell transistor MT is set in any one of the eight states, and can store 3-bit data. In addition, write and read are executed in units of a page in one cell unit CU. In a case where the memory cell transistor MT stores 3-bit data, a lower bit, a middle bit and an upper bit are allocated to three pages in one cell unit CU. Pages written in a single write operation or pages read in a single read operation in regard to the lower bit, middle bit and upper bit, that is, a set of lower bits, a set of middle bits and a set of upper bits stored in the cell unit CU, are referred to as a lower page, a middle page and an upper page, respectively.

In a case where the above-described allocation of data is applied, the lower page is determined by the read operation using the read voltages AR and ER. The middle page is determined by the read operation using the read voltages BR, DR and FR. The upper page is determined by the read operation using the read voltages CR and GR.

### 1.2. Operation of Memory System

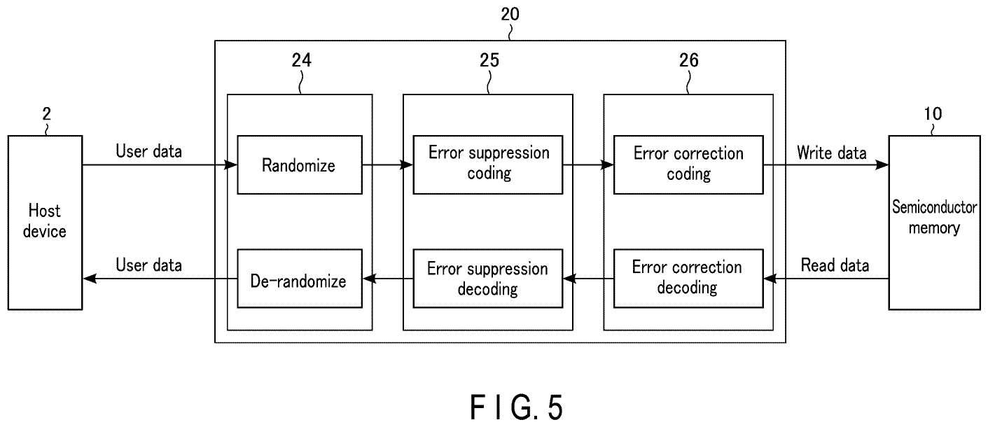

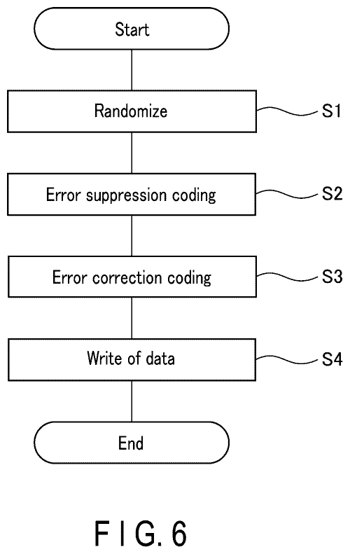

An outline of a write operation and a read operation in the memory system 1 of the first embodiment is described. FIG. 5 is a diagram illustrating a flow of data of the write operation and the read operation in the memory system of the first embodiment. FIG. 6 is a flowchart illustrating the write operation in the memory system.

In the write operation in the memory system 1, as illustrated in FIG. 5, the memory controller 20 successively executes randomize, error suppression coding, and error correction coding for user data that is input from the host device 2, and outputs the resultant user data as write data to the semiconductor memory 10. The semiconductor memory 10 writes the write data in the memory cell array 11.

Hereinafter, the write operation is described with reference to FIG. 6.

User data is sent from the host device 2 to the memory controller 20. The user data that is sent to the memory controller 20 is randomized by the randomizer 24, and randomize data is generated (S1). The randomize data is subjected to error suppression coding by the error suppression coding/decoding circuit 25, and the error-suppression-coded data (hereinafter referred to as “coded data”) is generated (S2). The coded data is subjected to error correction coding by the ECC circuit 26, and thereby write data is generated (S3). The write data is sent from the memory controller 20 to the semiconductor memory 10. The write data that is sent to the semiconductor memory 10 is written in, for example, the block BLKn in the memory cell array 11 of the semiconductor memory 10 (S4).

On the other hand, in the read operation in the memory system 1, a process reverse to the process in the write operation is executed. As illustrated in FIG. 5, the memory controller 20 successively executes error correction decoding, error suppression decoding and de-randomize for read data that is read from the semiconductor memory 10, and outputs the resultant read data as user data to the host device 2.

In the present embodiment, attention is paid to the process of the error suppression coding executed by the error suppression coding/decoding circuit 25 in the write operation, and a detailed method of this process is described. In the description below of the operation, a description of the processes by the randomizer 24 and ECC circuit 26, which are executed in the input stage and the output stage of the error suppression coding/decoding circuit 25, is omitted.

As described above, the error suppression coding and decoding aims at reducing the error rate of data, by executing data conversion on the data that is to be written in the semiconductor memory 10. The error rate of data can be expressed by, for example, a bit error rate (BER) or a frame error rate (FER). The BER is a ratio of the number of error bits to the total number of bits of transfer data. For example, at a time when write data, after written in the semiconductor memory 10, is read out, an error occurs in the read data. The BER is a ratio of error bits to the total number of bits of write data.

Coding parameters are used in the error suppression coding that is executed by the error suppression coding/decoding circuit 25. The coding parameters include two parameters. One parameter is a state control variable CO, and the other parameter is a coding rate CR. In the present specification, at least one parameter of the state control variable CO and the coding rate CR is referred to as “coding parameter”(or “coding condition”).

The state control variable CO is a variable that controls an occurrence probability of a state to which a memory cell belongs. The state control variable CO sets a ratio of the number of memory cells for each of states, in regard to the memory cells that a page includes. For example, in a case where the TLC is applied to the memory cell, the ratio of the number of memory cells is set for each state by the state control variable CO, in regard to the eight states of states Er to G.

The coding rate CR sets application or non-application of bit inversion for each of divided data, into which the user data is divided in units of a fixed quantity. The coding rate CR can be set for each page data.

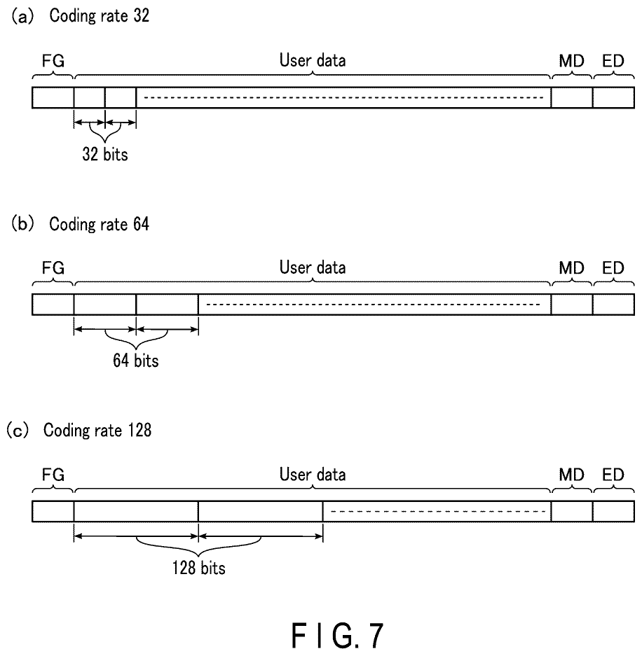

FIG. 7 is a diagram illustrating data formats to which various coding rates are applied. For example, user data is divided in units of 32 bits, 64 bits or 128 bits, and the application or non-application of bit inversion is set for each divided data.

As illustrated in part (a) of FIG. 7, in a case where a coding rate 32 is set, the user data is divided in units of 32 bits. Further, a flag FG indicating application or non-application of bit inversion is added to the user data.

Similarly, as illustrated in part (b) of FIG. 7, in a case where a coding rate 64 is set, the user data is divided in units of 64 bits. Further, the flag FG indicating application or non-application of bit inversion is added to the user data.

As illustrated in part (c) of FIG. 7, In a case where a coding rate 128 is set, the user data is divided in units of 128 bits. Further, the flag FG indicating application or non-application of bit inversion is added to the user data. The flag FG is referred to, at a time of executing error suppression decoding on the read data that is read from the semiconductor memory 10.

The coding parameters, i.e., the state control variable CO and the coding rate CR, are stored, for example, in the RAM 22 in the memory controller 20. In a case where the error suppression coding is executed by the error suppression coding/decoding circuit 25, the memory controller 20 reads out the coding parameters stored in the RAM 22, and executes, based on the coding parameters, the error suppression coding on the user data received from the host device 2.

The write data, which is sent from the memory controller 20 to the semiconductor memory 10, includes management data MD and ECC data ED, as well as the user data and the flag FG. The management data MD includes various data that the memory controller 20 uses in the write operation and the read operation. The ECC data ED includes data (for example, parity bit) generated by the error correction coding of the ECC circuit 26.

In addition, the coding rate CR can be set at different values for the respective pages. For example, in a case where the TLC is applied to the memory cell, coding rates can be set for the lower page, middle page and upper page, respectively.

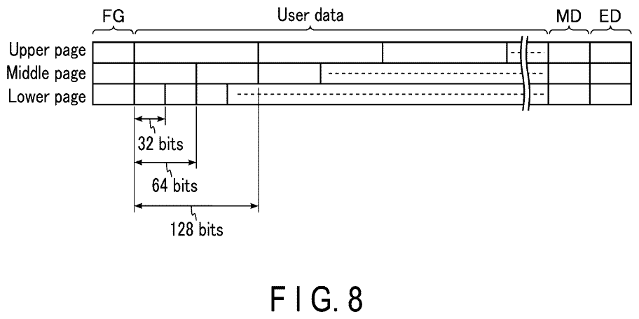

FIG. 8 is a diagram illustrating an example of a case where coding rates are set for a plurality of pages. For example, the coding rate 32 is set for the lower page, the coding rate 64 is set for the middle page, and the coding rate 128 is set for the upper page. Note that there is a case where a coding rate 0 is set, and bit inversion is not applied to the page.

Next, a description is given of the write operation and read operation in the memory system 1 of the first embodiment, and the operation of the error suppression coding in the error suppression coding/decoding circuit 25.

In the write operation in the memory system 1, user data is first sent from the host device 2 to the memory controller 20. With respect to the user data received from the host device 2, the memory controller 20 determines a block in the memory cell array 11 of the semiconductor memory 10, in which the user data is to be written, that is, a block of a write destination (hereinafter, “target block”) BLKn. The memory controller 20 reads out the coding parameters corresponding to the target block BLKn from the RAM 22. Using the read-out coding parameters, the memory controller 20 executes error suppression coding on the user data, and generates write data. The memory controller 20 sends the write data to the semiconductor memory 10. The semiconductor memory 10 writes the write data, which is received from the memory controller 20, into the memory cells coupled to word lines in the target block BLKn of the memory cell array 11.

The read operation in the memory system 1 is as follows. The data written in the memory cells coupled to the word lines in the target block BLKn is read out by the semiconductor memory 10 and sent to the memory controller 20 as read data. The memory controller 20 reads out the coding parameters corresponding to the target block BLKn from the RAM 22. Using the read-out coding parameters and the flag FG included in the read data, the memory controller 20 executes error suppression decoding on the read data, and decodes the user data. The decoded user data is sent from the memory controller 20 to the host device 2.

Next, the error suppression coding in the write operation of the memory system 1 of the first embodiment is described.

In the write operation, error suppression coding is executed by the error suppression coding/decoding circuit 25 for the write data that is to be written in the memory cells coupled to word lines in the target block BLKn. Thereafter, from among the word lines in the target block BLKn, a word line (hereinafter referred to as “target word line”) WL, in regard to which an error rate BER of read data is not improved from an expected value, is selected. Then, optimization of the coding parameters used in the error suppression coding is executed for the write data that is to be written in the memory cells coupled to the target word line WL. Note that the target word line WL that is selected may be a single word line or a plurality of word lines.

In the optimization of the coding parameters, N (N is an integer of 1 or more) coding rates are set for the write data that is to be written in the memory cells coupled to the target word line WL, and the optimization of the state control variable CO is executed for the write data of each coding rate. Then, a coding rate indicating a smallest error rate, among the error rates obtained by the error suppression coding in which the state control variable CO is optimized, is selected.

For example, the N coding rates are set as follows. In a case where the target word line WL includes three pages (lower page, middle page and upper page) and each page can take four coding rates 0, 32, 64 and 128, 64 coding rates are set for the target word line WL.

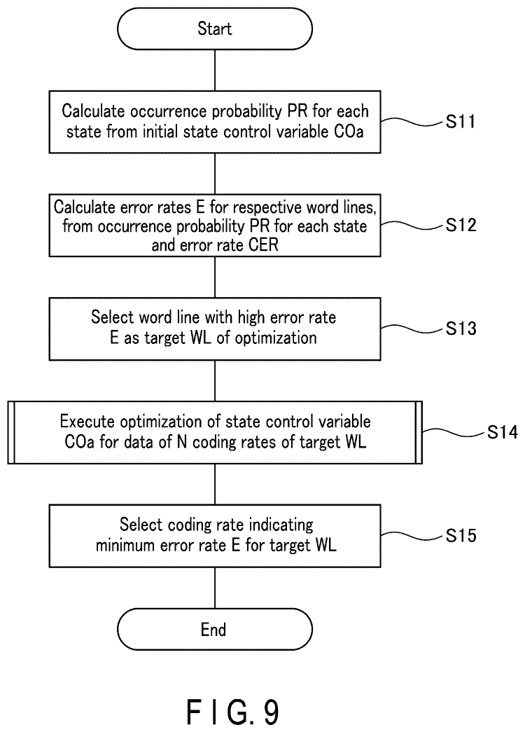

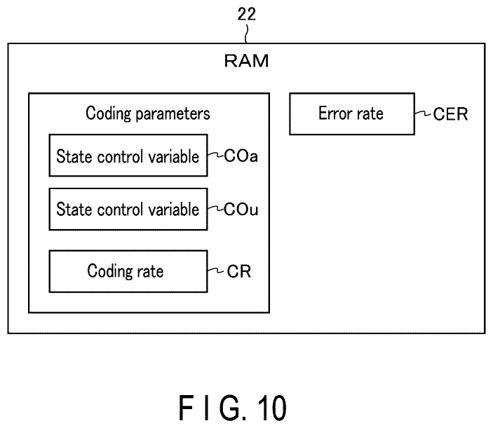

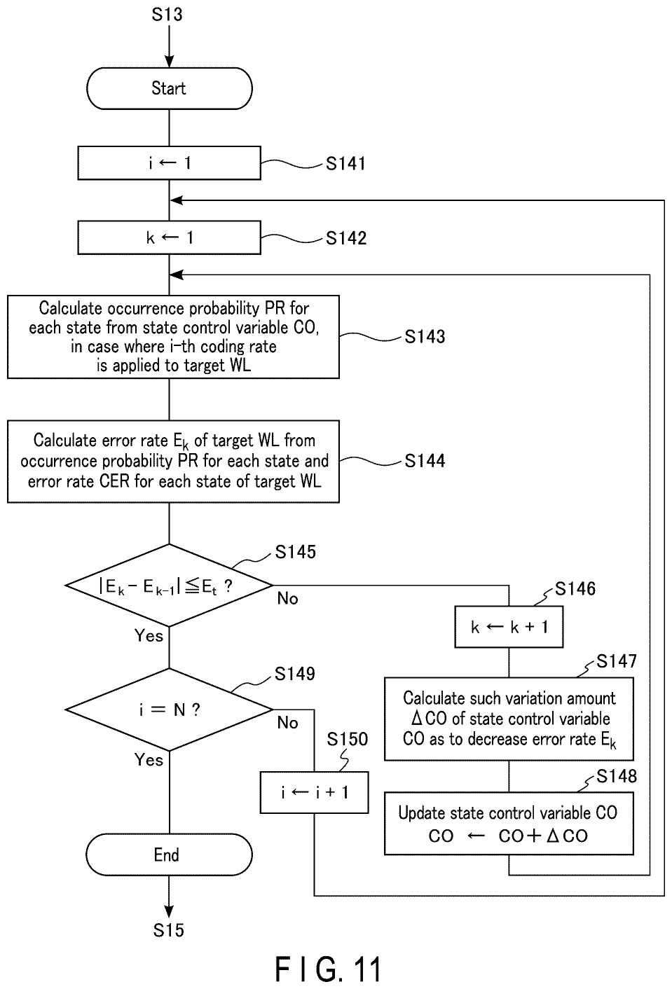

Hereinafter, referring to FIG. 9, FIG. 10 and FIG. 11, a description is given of a process of optimization of the coding parameters in the error suppression coding of the memory system of the first embodiment.

FIG. 9 is a flowchart illustrating a process of optimization of the coding parameters in the error suppression coding of the memory system of the first embodiment. The process of the optimization of the coding parameters is controlled by the memory controller 20 (or the processor 21).

FIG. 10 is a diagram illustrating information stored in the RAM 22 used in the process of the optimization of the coding parameters. The RAM 22 stores the coding parameters including the state control variable CO and the coding rate CR, and an error rate CER. In the description using FIG. 9 to FIG. 11, an initial state control variable is described as COa, and an updated state control variable is described as COu. In a case of describing the state control variable CO, it is assumed that the state control variable CO includes at least one of the state control variables COa and COu.

Prior to use by a user, an initial operation test is executed for the semiconductor memory 10, and the coding parameters and error rate CER are set or calculated by using the test data obtained by the operation test. The coding parameters that are set include the initial state control variable COa that is applied to the word lines in the target block BLKn. The calculated error rate CER is a cell error rate (CER), and, for example, in the case of applying the TLC to the memory cell, the error rate CER is calculated for each of the eight states Er to G.

An average value of the error rates CER of the states is calculated, and the state control variable COa is calculated based on the average value of the error rates CER. Specifically, the state control variable COa is calculated such that, among the error rates CER calculated for the states, the number of memory cells belonging to a state in which the CER is higher than the average value decreases, and the number of memory cells belonging to a state in which the CER is lower than the average value increases.

In the memory cell array 11 of the semiconductor memory 10, in usual cases, there exists a storage area in which setting information necessary for operations is stored. For example, here, the storage area is referred to as “ROM block”. The state control variables COa (and COu) and the error rate CER are stored in the ROM block provided in the memory cell array 11.

At a time of powering on the memory system 1, the memory controller 20 reads out the state control variables COa (and COu) and the error rate CER from the ROM block, and stores them in the RAM 22. Where necessary, the memory controller 20 reads out the state control variable COa and the error rate CER from the RAM 22, and uses them for the process of optimization of the coding parameters.

Hereinafter, referring to FIG. 9, the process of optimization of the coding parameters is described.

To start with, the memory controller 20 calculates an occurrence probability PR for each state from the state control variable COa that is read from the RAM 22 (S11).

Next, the memory controller 20 calculates error rates E for the respective word lines, from the occurrence probability PR for each state and the error rate CER that is read out from the RAM 22 (S12).

Subsequently, the memory controller 20 compares the calculated error rates E for the word lines, and selects, for example, a word line with a highest error rate, as a target word line WL for optimization of the coding parameters (S13).

Next, the memory controller 20 applies N coding rates to the write data that is to be written in the memory cells of the target word line WL selected from the target block BLKn. Further, the memory controller 20 executes optimization of the state control variable COa for the write data to which the N coding rates are applied (S14). The details of the optimization of the state control variable COa will be described later.

Then, the memory controller 20 selects a coding rate indicating a smallest error rate E of read data, in relation to the write data that is written in the memory cells of the target word line WL (S15).

By the above, the optimization of the coding parameters (i.e., the state control variable COa and coding rate CR), which are used in the error suppression coding for the target word line WL, is completed.

Note that in the subsequent write operation, the error suppression coding is executed based on the optimized coding parameters, in regard to the write data for the target word line WL in the target block BLKn. In regard to the write data for the other word lines in the target block BLKn, the error suppression coding is executed based on initial coding parameters.

Next, the optimization of the state control variable COa described in step S14 is described in detail. FIG. 11 is a flowchart illustrating an optimizing process of the state control variable COa.

To start with, the memory controller 20 substitutes 1 for variables i and k (S141 and S142). The variable i indicates a sequential number of a coding rate among the N coding rates. The variable i is an integer of 1 or more, and N or less. N is the number of coding rates, and is an integer of 1 or more. The variable k is a number of loops of a process for minimizing the error rate, i.e., a process for optimizing the state control variable COa. The variable k is an integer of 1 or more.

Next, the memory controller 20 calculates the occurrence probability PR for each state from the state control variable CO, in a case where an i-th coding rate is applied to the write data that is to be written in the memory cells of the target word line WL (S143). Note that the state control variable COa is used for the calculation of the initial occurrence probability PR, and the state control variable COu is used for the calculation of the second and following occurrence probability PR.

Next, the memory controller 20 calculates an error rate Eₖ of read data that is read from the memory cells of the target word line WL, from the occurrence probability PR for each state and the error rate CER for each state in the target word line WL (S144).

Next, the memory controller 20 subtracts a previously calculated error rate Eₖ₋₁ from a currently calculated error Eₖ, and calculates a decrease value (or a variation amount) of the error rate Eₖ. In addition, the memory controller 20 determines whether the decrease value of the error rate Eₖ is equal to or less than a predetermined threshold Eₜ (S145).

If the decrease value of the error rate Eₖ is greater than the threshold Eₜ (No), The memory controller 20 increments k (S146). Further, the memory controller 20 calculates such a variation amount ΔCO of the state control variable CO as to decrease the error rate Eₖ (S147). In the calculation of the variation amount ΔCO, use is made of a local optimization method such as a gradient descent or a Nelder Mead method. Note that the object of the first calculation of the variation amount ΔCO is the state control variable COa, and the object of the second and following calculation of the variation amount ΔCO is the state control variable COu.

Next, the memory controller 20 updates the state control variable CO to a new state control variable CO to which the variation amount ΔCO is added (S148). Note that in the first update of the state control variable, the variation amount ΔCO is added to the state control variable COa, and in the second and following update of the state control variable, the variation amount ΔCO is added to the state control variable COu. Thereafter, the memory controller 20 goes to the process of step S143, and executes the process of step S143 onwards. Specifically, the memory controller 20 updates the state control variable CO by varying the state control variable CO in units of the variation amount ΔCO, until the decrease value of the error rate Eₖ decreases to the threshold Eₜ or less.

On the other hand, in step S145, if the decrease amount of the error rate Eₖ is the threshold Eₜ or less (Yes), the memory controller 20 determines whether the variable i is equal to N (S149). If the variable i is not equal to N (No), the memory controller 20 increments the variable i (S150), and goes to the process of step S142 and executes the process of step S142 onwards. Specifically, the memory controller 20 repeats the process of step S142 onwards, until the variable i becomes equal to N, or, in other words, until the end of the calculation in the case where the N-th coding rate is applied to the write data that is to be written in the memory cells of the target word line WL.

On the other hand, in step S149, if the variable i is equal to N (Yes), the memory controller 20 ends the process of optimization of the state control variable COa, and advances to step S15.

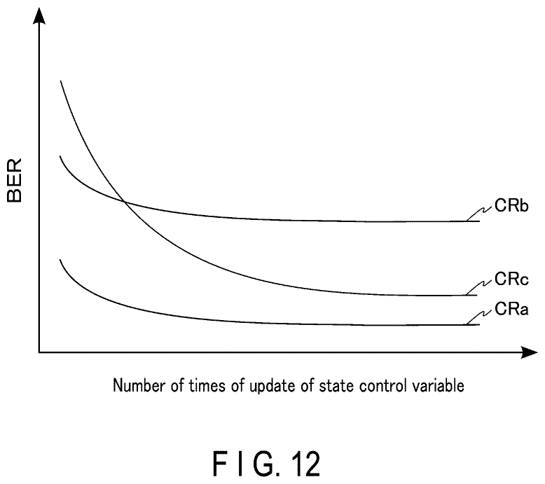

FIG. 12 is a graph illustrating variations of error rates E by an optimizing process in error suppression coding of the memory system of the first embodiment. FIG. 12 represents the BER as the error rate E in regard to different coding rates CRa, CRb and CRc. For example, CRa is the coding rate 32, CRb is the coding rate 64, and CRc is the coding rate 128.

As illustrated in FIG. 12, in regard to each of the data to which the coding rates are applied, the BER can be decreased by repeating the update of the state control variable CO in steps S143 to S148. As regards the coding rates illustrated here, the coding rate CRa indicating the smallest error rate E is selected in step S15.

### 1.3. Advantageous Effects of First Embodiment

According to the first embodiment, there can be provided a memory system that can improve the reliability in the write and read of data.

For example, in a case where the error suppression coding is performed for the data that is to be written in the memory cells coupled to all word lines in the block of the write target, there is a case where a word line (target word line), with respect to which the error rate of read data is not improved from an expected value, is present. In the first embodiment, the optimization of the error suppression coding is executed for the data that is written in the memory cells coupled to this target word line. The optimization of the state control variable CO is first executed for the data of each of the N coding rates, among the coding parameters in the error suppression coding, and the coding rate with the lowest error rate is selected. Then, the error suppression coding is executed based on the selected coding parameter, for the data that is to be written in the memory cells coupled to the target word line.

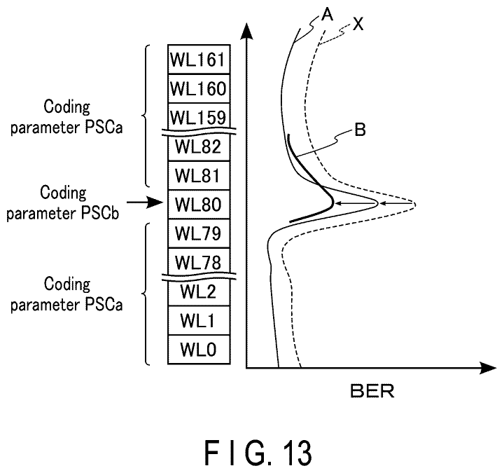

FIG. 13 is a diagram illustrating BERs (FERs) in regard to word lines in a case where error suppression coding is performed for write data that is to be written in memory cells coupled to all word lines and a target word line in a target block. In FIG. 13, the number of word lines in the target block is 162, and these word lines are indicated by WL0 to WL161. The abscissa axis indicates the BERs of read data that is read out from the word lines in the target block, and the ordinate axis indicates positions of the word lines in the target block.

FIG. 13 illustrates, by A, a BER in a case where error suppression coding was performed based on an identical coding parameter PSCa, for data that is written in the memory cells coupled to all word lines in the target block, and illustrates, by X, a BER in a case where error suppression coding is not performed. Further, FIG. 13 illustrates, by B, a BER in a case where error suppression coding was performed based on an optimized coding parameter PSCb, for the data that is written in the memory cells coupled to the target word line.

As indicated by A in FIG. 13, in the case where the error suppression coding was performed based on the identical coding parameter PSCa, in regard to all word lines in the target block, the BER decreases in regard to all word lines, but there exists a word line WL80 in regard to which the BER does not decrease to an expected value.

In the first embodiment, the word line WL80, in regard to which the BER does not decrease to the expected value as described above, i.e., the word line WL80, in regard to which the BER is not improved, is selected.

Then, the optimization of the coding parameter in the error suppression coding is executed for the selected word line (hereinafter “target word line”) WL80. The coding parameter PSCb used in the error suppression coding is optimized for the data that is written in the target word line WL80, in such a manner that the BER in the read data from the target word line WL80 decreases. Thereby, as indicated by B in FIG. 13, the BER in the read data that is read from the target word line WL80 can be decreased.

As described above, according to the memory system of the first embodiment, the reliability in the write and read of data can be improved.

### 2. Second Embodiment

A memory system of a second embodiment is described. In the second embodiment, the optimization of the coding rate is first executed for the data that is written in the memory cells coupled to the target word line WL in the target block BLKn, and then the optimization of the state control variable CO is executed for the data to which the optimized coding rate was applied. In the second embodiment, different points from the first embodiment are mainly described. The other structure that is not described in the second embodiment is similar to the first embodiment.

### 2.1. Operation of Memory System

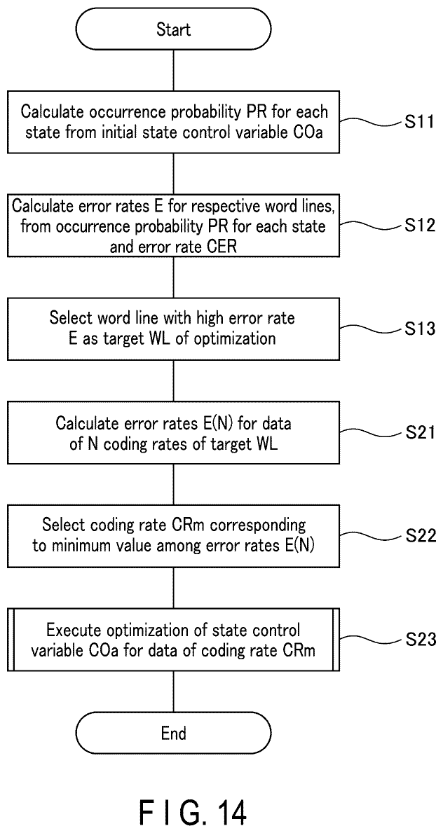

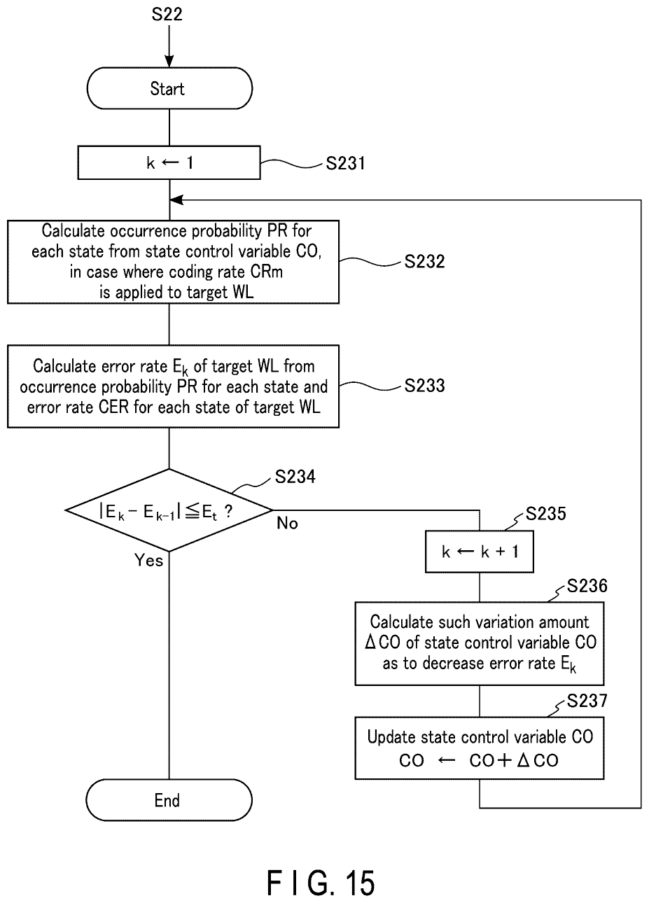

Referring to FIG. 14 and FIG. 15, a description is given of a process of optimization of coding parameters in the error suppression coding of the memory system of the second embodiment.

FIG. 14 is a flowchart illustrating the process of optimization of the coding parameters in the error suppression coding of the memory system of the second embodiment. The process of optimization of the coding parameters is controlled by the memory controller 20 (or the processor 21). In the description referring to FIG. 14 and FIG. 15, an initial state control variable is described as COa, and an updated state control variable is described as COu. In a case of describing the state control variable CO, it is assumed that the state control variable CO includes at least one of the state control variables COa and COu.

As described above, an initial operation test is executed for the semiconductor memory 10, and the state control variable COa and error rate CER are set or calculated by using the test data obtained by the operation test. The state control variables COa (and COu) and the error rate CER are stored in the RAM 22. The memory controller 20 reads out the state control variable COa and the error rate CER from the RAM 22, and uses them for the process of optimization of the coding parameters.

Hereinafter, referring to FIG. 14, the process of optimization of the coding parameters is described.

To start with, the memory controller 20 calculates an occurrence probability PR for each state from the state control variable COa that is read from the RAM 22 (S11).

Next, the memory controller 20 calculates error rates E for the respective word lines, from the occurrence probability PR for each state and the error rate CER that is read out from the RAM 22 (S12).

Then, the memory controller 20 compares the calculated error rates E for the word lines, and selects, for example, a word line with a highest error rate, as a target word line WL for optimization of the coding parameters (S13).

Next, the memory controller 20 applies N coding rates to the write data that is to be written in the memory cells of the target word line WL in the target block BLKn. Further, the memory controller 20 calculates error rates E(N) of read data obtained in regard to the write data to which the N coding rates were applied (S21).

Then, the memory controller 20 selects a coding rate CRm corresponding to a minimum value among the calculated error rates E(N) (S22).

Next, the memory controller 20 executes optimization of the state control variable COa for the write data to which the coding rate CRm is applied (S23). Specifically, the memory controller 20 executes optimization of the state control variable COa for the data obtained by applying the coding rate CRm to the write data that is written in the memory cells of the target word line WL. The details of the optimization of the state control variable COa will be described later.

By the above, the optimization of the coding parameters (i.e., the coding rate CR and state control variable COa), which are used in the error suppression coding for the target word line WL, is completed.

Note that in the subsequent write operation, the error suppression coding is executed based on the optimized coding parameters, in regard to the write data for the target word line WL in the target block BLKn. In regard to the write data for the other word lines in the target block BLKn, the error suppression coding is executed based on initial coding parameters.

Next, the optimization of the state control variable COa described in step S23 is described in detail. FIG. 15 is a flowchart illustrating an optimizing process of the state control variable COa.

To start with, the memory controller 20 substitutes 1 for a variable k (S231). The variable k is a number of loops of a process for optimizing the state control variable COa. The variable k is an integer of 1 or more.

Next, the memory controller 20 calculates the occurrence probability PR for each state from the state control variable CO, in a case where the coding rate CRm is applied to the write data that is to be written in the memory cells of the target word line WL (S232). Note that the state control variable COa is used for the first calculation of the occurrence probability PR, and the state control variable COu is used for the second and following calculation of the occurrence probability PR.

Next, the memory controller 20 calculates an error rate Eₖ of read data that is read from the memory cells of the target word line WL, from the occurrence probability PR for each state and the error rate CER for each state in the target word line WL (S233).

Next, the memory controller 20 subtracts a previously calculated error rate Eₖ₋₁ from a currently calculated error Eₖ, and calculates a decrease value of the error rate Eₖ. In addition, the memory controller 20 determines whether the decrease value of the error rate Eₖ is equal to or less than a predetermined threshold Eₜ (S234).

If the decrease value of the error rate Eₖ is greater than the threshold Eₜ (No), The memory controller 20 increments k (S235). Further, the memory controller 20 calculates such a variation amount ΔCO of the state control variable CO as to decrease the error rate Eₖ (S236). In the calculation of the variation amount ΔCO, use is made of a local optimization method such as a gradient descent or a Nelder Mead method. Note that the object of the first calculation of the variation amount ΔCO is the state control variable COa, and the object of the second and following calculation of the variation amount ΔCO is the state control variable COu.

Next, the memory controller 20 updates the state control variable CO to a new state control variable CO to which the variation amount ΔCO is added (S237). Note that in the first update of the state control variable, the variation amount ΔCO is added to the state control variable COa, and in the second and following update of the state control variable, the variation amount ΔCO is added to the state control variable COu. Thereafter, the memory controller 20 goes to the process of step S232, and executes the process of step S232 onwards.

On the other hand, in step S234, if the decrease amount of the error rate Eₖ is the threshold Eₜ or less (Yes), the memory controller 20 terminates the process of optimization of the state control variable COa, and terminates the process of the error suppression coding.

Specifically, the memory controller 20 updates the state control variable CO by varying the state control variable CO in units of the variation amount ΔCO, until the decrease value of the error rate Eₖ decreases to the threshold Eₜ or less. In addition, if the decrease value of the error rate Eₖ decreases to the threshold Eₜ or less, the memory controller 20 terminates the process of the error suppression coding.

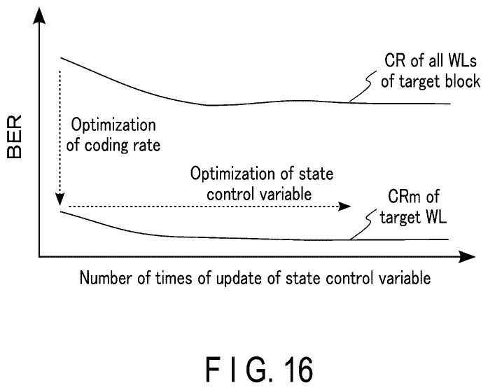

FIG. 16 is a graph illustrating variations of error rates E by an optimizing process in the error suppression coding of the memory system according to the second embodiment. FIG. 16 illustrates a BER relating to the coding rate CRm of the target word line, and a BER relating to the coding rate CR of all word lines in the target block.

As illustrated in FIG. 16, in the error suppression coding, the optimization of the coding rate, i.e., the coding rate CRm, is selected, and the optimization of the state control variable CO is executed, and thereby the BER relating to the write data to be written in the memory cells of the target word line can be reduced.

### 2.3. Advantageous Effects of Second Embodiment

According to the second embodiment, there can be provided a memory system that can improve the reliability in the write and read of data.

In the second embodiment, the optimization of the coding rate is first executed for the data that is written in the memory cells coupled to the target word line, and then the optimization of the state control variable CO is executed for the data to which the optimized coding rate was applied. In addition, the error suppression coding is executed based on the optimized coding parameters, i.e., the optimized coding rate and state control variable, in regard to the data to be written in the memory cells coupled to the target word line.

As described above, according to the memory system of the second embodiment, the reliability in the write and read of data can be improved.

Furthermore, in the above-described embodiments, the NAND flash memory was described as an example of the semiconductor memory, but the semiconductor memory is not limited to the NAND flash memory. The embodiments are applicable to other semiconductor memories in general, and are also applicable to various memory devices other than semiconductor memories. Besides, the order of processes in the flowcharts described in the embodiments can be changed as much as possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a semiconductor memory including a plurality of word lines to which a plurality of memory cells are coupled; and
a memory controller configured to execute error suppression coding for data that is to be written in the semiconductor memory,
wherein the memory controller is configured to:
generate first write data by executing the error suppression coding, based on a first coding parameter, in regard to data that is to be written in the memory cells coupled to the word lines;
read out the first write data that is written in the memory cells, as first read data;
calculate an error rate for each of the word lines from the first read data, and select a first word line from the word lines, based on the error rate for each of the word lines;
generate second write data by executing the error suppression coding while varying the first coding parameter, in regard to data that is to be written in a first memory cell coupled to the first word line;
set a second coding parameter, based on an error rate of second read data corresponding to the second write data; and
execute error suppression coding, based on the second coding parameter, in regard to data that is to be written in the first memory cell coupled to the first word line.

2. The memory system according to claim 1, wherein
each of the memory cells coupled to the word lines has a threshold voltage,
the threshold voltage that each of the memory cells has belongs to one of a plurality of states to which a plurality of voltage distributions are allocated, and
each of the first coding parameter and the second coding parameter includes a control variable including a ratio of a number of memory cells belonging to each of the states.

3. The memory system according to claim 2, wherein the memory controller is configured to calculate the control variable included in the second coding parameter, from a value at which the error rate of the second read data takes a minimum value, while varying the control variable included in the first coding parameter.

4. The memory system according to claim 1, wherein
the first coding parameter includes a first coding rate for setting a first data amount at a time of dividing, in units of the first data amount, the data to be written in the memory cells coupled to the word lines;
the second coding parameter includes a second coding rate for setting a second data amount at a time of dividing, in units of the second data amount, the data to be written in the first memory cell coupled to the first word line; and
the memory controller is configured to:
set presence or absence of data inversion for each of divisional data divided by the first coding rate, in the error suppression coding based on the first coding parameter; and
set presence or absence of data inversion for each of divisional data divided by the second coding rate, in the error suppression coding based on the second coding parameter.

5. The memory system according to claim 2, wherein
the first coding parameter includes a first coding rate for setting a first data amount at a time of dividing, in units of the first data amount, the data to be written in the memory cells coupled to the word lines;
the second coding parameter includes a second coding rate for setting a second data amount at a time of dividing, in units of the second data amount, the data to be written in the first memory cell coupled to the first word line;
the memory controller is configured to:
set presence or absence of data inversion for each of divisional data divided by the first coding rate, in the error suppression coding based on the first coding parameter; and
set presence or absence of data inversion for each of divisional data divided by the second coding rate, in the error suppression coding based on the second coding parameter, and
the memory controller, in the setting of the second coding parameter, is configured to:
generate a plurality of the second write data by executing the error suppression coding while varying the control variable, by using each of a plurality of the second coding rates and the control variable, in regard to the data to be written in the first memory cell; and
select the second coding rate included in the second coding parameter from among the plurality of the second coding rates, by using a value at which the error rate of the second read data in regard to each of the plurality of the second write data takes a minimum value.

6. The memory system according to claim 2, wherein
the first coding parameter includes a first coding rate for setting a first data amount at a time of dividing, in units of the first data amount, the data to be written in the memory cells coupled to the word lines;
the second coding parameter includes a second coding rate for setting a second data amount at a time of dividing, in units of the second data amount, the data to be written in the first memory cell coupled to the first word line;
the memory controller is configured to:
set presence or absence of data inversion for each of divisional data divided by the first coding rate, in the error suppression coding based on the first coding parameter; and
set presence or absence of data inversion for each of divisional data divided by the second coding rate, in the error suppression coding based on the second coding parameter, and
the memory controller, in the setting of the second coding parameter, is configured to:
generate a plurality of the second write data by executing the error suppression coding, by using each of a plurality of the second coding rates and the control variable, in regard to the data to be written in the first memory cell;
select the second coding rate included in the second coding parameter from among the plurality of the second coding rates, by using a value at which the error rate of the second read data in regard to each of the plurality of the second write data takes a minimum value;
generate a plurality of the second write data by executing the error suppression coding while varying the control variable, by using the selected second coding rate and the control variable, in regard to the data to be written in the first memory cell; and
calculate the control variable included in the second coding parameter from a value at which the error rate of the second read data in regard to each of the plurality of the second write data takes a minimum value.

7. The memory system according to claim 1, wherein
the error rate for each of the word lines is calculated for each of the word lines, and is a ratio of a number of error bits to a total number of bits of the data to be written in the memory cells coupled to each of the word lines, and
the error rate of the second read data is a ratio of a number of error bits occurring in the second read data to a total number of bits of the second write data.

8. The memory system according to claim 1, wherein the first word line includes one or more word lines.

9. The memory system according to claim 1, wherein the memory controller is configured to:
generate a plurality of the second write data by executing the error suppression coding while varying the first coding parameter; and
terminate the varying of the first coding parameter in a case where a variation amount of the error rate of a plurality of the second read data in regard to the plurality of the second write data decreases to a threshold or less, and set the first coding parameter at a time of the terminating as the second coding parameter.

10. The memory system according to claim 1, wherein
the data to be written in the first memory cell coupled to the first word line includes a plurality of pages, and
the memory controller is configured to set the second coding parameter for each of the pages by executing the error suppression coding.

11. The memory system according to claim 2, wherein the memory controller is configured to:
calculate an error rate for each of the states from the first read data;
calculate an average value of the error rates of the states, and generate the control variable from the average value of the error rates;
calculate, based on the control variable, an occurrence probability for each of the states corresponding to the data to be written in the first memory cell coupled to the first word line; and
calculate the error rate of the second read data from the occurrence probability for each of the states and the error rate for each of the states in regard to the first word line.

12. The memory system according to claim 1, wherein
the semiconductor memory includes a plurality of conductive layers including the word lines, and a pillar,
the conductive layers extend in a first direction and are stacked in a second direction crossing the first direction, and
the pillar extends in the second direction and penetrates the conductive layers.

13. The memory system according to claim 12, wherein portions at which the conductive layers and the pillar intersect function as memory cells.

14. The memory system according to claim 1, wherein the semiconductor memory includes a NAND flash memory in which memory cells are three-dimensionally arranged.

15. A writing method for a semiconductor memory comprising:
generating first write data by executing an error suppression coding, based on a first coding parameter, in regard to data that is to be written in memory cells coupled to word lines in the semiconductor memory;
reading out the first write data that is written in the memory cells, as first read data;
calculating an error rate for each of the word lines from the first read data, and select a first word line from the word lines, based on the error rate for each of the word lines;
generating second write data by executing the error suppression coding while varying the first coding parameter, in regard to data that is to be written in a first memory cell coupled to the first word line;
setting a second coding parameter, based on an error rate of second read data corresponding to the second write data; and
executing error suppression coding, based on the second coding parameter, in regard to data that is to be written in the first memory cell coupled to the first word line.

16. The writing method according to claim 15, wherein each of the memory cells coupled to the word lines has a threshold voltage,
the threshold voltage that each of the memory cells has belongs to one of a plurality of states to which a plurality of voltage distributions are allocated, and
each of the first coding parameter and the second coding parameter includes a control variable including a ratio of a number of memory cells belonging to each of the states.

17. The writing method according to claim 16, wherein calculating the control variable included in the second coding parameter, from a value at which the error rate of the second read data takes a minimum value, while varying the control variable included in the first coding parameter.

18. The writing method according to claim 15, wherein the first coding parameter includes a first coding rate for setting a first data amount at a time of dividing, in units of the first data amount, the data to be written in the memory cells coupled to the word lines,
the second coding parameter includes a second coding rate for setting a second data amount at a time of dividing, in units of the second data amount, the data to be written in the first memory cell coupled to the first word line,
setting presence or absence of data inversion for each of divisional data divided by the first coding rate, in the error suppression coding based on the first coding parameter, and
setting presence or absence of data inversion for each of divisional data divided by the second coding rate, in the error suppression coding based on the second coding parameter.

19. The writing method according to claim 16, wherein the first coding parameter includes a first coding rate for setting a first data amount at a time of dividing, in units of the first data amount, the data to be written in the memory cells coupled to the word lines,
the second coding parameter includes a second coding rate for setting a second data amount at a time of dividing, in units of the second data amount, the data to be written in the first memory cell coupled to the first word line,
setting presence or absence of data inversion for each of divisional data divided by the first coding rate, in the error suppression coding based on the first coding parameter,
setting presence or absence of data inversion for each of divisional data divided by the second coding rate, in the error suppression coding based on the second coding parameter,
in the setting of the second coding parameter, generating a plurality of the second write data by executing the error suppression coding while varying the control variable, by using each of a plurality of the second coding rates and the control variable, in regard to the data to be written in the first memory cell, and
selecting the second coding rate included in the second coding parameter from among the plurality of the second coding rates, by using a value at which the error rate of the second read data in regard to each of the plurality of the second write data takes a minimum value.

20. The writing method according to claim 16, wherein the first coding parameter includes a first coding rate for setting a first data amount at a time of dividing, in units of the first data amount, the data to be written in the memory cells coupled to the word lines,
the second coding parameter includes a second coding rate for setting a second data amount at a time of dividing, in units of the second data amount, the data to be written in the first memory cell coupled to the first word line,
setting presence or absence of data inversion for each of divisional data divided by the first coding rate, in the error suppression coding based on the first coding parameter,
setting presence or absence of data inversion for each of divisional data divided by the second coding rate, in the error suppression coding based on the second coding parameter,
in the setting of the second coding parameter, generating a plurality of the second write data by executing the error suppression coding, by using each of a plurality of the second coding rates and the control variable, in regard to the data to be written in the first memory cell,
selecting the second coding rate included in the second coding parameter from among the plurality of the second coding rates, by using a value at which the error rate of the second read data in regard to each of the plurality of the second write data takes a minimum value,
generating a plurality of the second write data by executing the error suppression coding while varying the control variable, by using the selected second coding rate and the control variable, in regard to the data to be written in the first memory cell, and
calculating the control variable included in the second coding parameter from a value at which the error rate of the second read data in regard to each of the plurality of the second write data takes a minimum value.
